(19) United States
(12) Patent Application Publication
(10) Pub. No.: US 2026/0032859 A1
(43) Pub. Date: Jan. 29, 2026

(54) JOINT ASSEMBLY, ELECTRONIC APPARATUS AND RACK MODULE

(71) Applicant: WISTRON CORP., New Taipei City (TW)

(72) Inventor: YU WEI LIN, New Taipei City (TW)

(21) Appl. No.: 18/942,843

(22) Filed: Nov. 11, 2024

(30) Foreign Application Priority Data
Jul. 26, 2024 (TW) 113127797

(51) Int. Cl. H05K 7/20

(52) U.S. Cl. CPC H05K 7/20272; H05K 7/20781

(57) ABSTRACT

A joint assembly is configured to be disposed on a plate. The joint assembly includes a mount seat, a first eccentric component, a second eccentric component, and a joint. The mount seat is configured to be disposed on the plate, and the mount seat has a first mount hole. The first eccentric component is rotatably disposed in the first mount hole. The first eccentric component has a second mount hole, and a central line of the second mount hole is non-overlapped with a central line of the first mount hole. The second eccentric component is rotatably disposed in the second mount hole. The joint is connected to the second eccentric component, and a central line of the joint is non-overlapped with the central line of the second mount hole.

### CROSS-REFERENCE TO RELATED APPLICATIONS

This non-provisional application claims priority under 35 U.S.C. § 119(a) on Patent Application No(s). 113127797 filed in Taiwan, R.O.C. on Jul. 26, 2024, the entire contents of which are hereby incorporated by reference.

### TECHNICAL FIELD

The disclosure relates to a joint assembly, an electronic apparatus and a rack module.

### BACKGROUND

As cloud and artificial intelligence technologies develop, servers currently equip with high-performance and high-power processors. In order to maintain such processors to operate in high performance and high efficiency, liquid cooling is usually used to dissipate heat for these processors.

Generally, a server is installed in a rack and connected to manifolds through quick release joints, so that a liquid cooling distribution unit (i.e., CDU) in the rack and the server can form a loop through the manifolds for circulation of coolant. However, during the process of connecting the joint of the server with the joint of one of the manifolds, the central lines of the joints may not be aligned with each other due to installation tolerance, such that after two joints are assembled each other, there may be a lateral force applied in the joints, which may adversely affect the connection between the joints and thus may occur leakage.

### SUMMARY

The disclosure provides a joint assembly, an electronic apparatus and a rack module which are capable of addressing aforementioned issues.

One embodiment of the disclosure provides a joint assembly. The joint assembly is configured to be disposed on a plate. The joint assembly includes a mount seat, a first eccentric component, a second eccentric component, and a joint. The mount seat is configured to be disposed on the plate, and the mount seat has a first mount hole. The first eccentric component is rotatably disposed in the first mount hole. The first eccentric component has a second mount hole, and a central line of the second mount hole is non-overlapped with a central line of the first mount hole. The second eccentric component is rotatably disposed in the second mount hole. The joint is connected to the second eccentric component, and a central line of the joint is non-overlapped with the central line of the second mount hole.

Another embodiment of the disclosure provides an electronic apparatus. The electronic apparatus includes a main body and a joint assembly. The main body has a plate. The joint assembly includes a mount seat, a first eccentric component, a second eccentric component, and a joint. The mount seat is disposed on the plate, and the mount seat has a first mount hole. The first eccentric component is rotatably disposed in the first mount hole. The first eccentric component has a second mount hole, and a central line of the second mount hole is non-overlapped with a central line of the first mount hole. The second eccentric component is rotatably disposed in the second mount hole. The joint is connected to the second eccentric component, and a central line of the joint is non-overlapped with the central line of the second mount hole.

Still another embodiment of the disclosure provides a rack module. The rack module includes a rack, a plurality of connection joints and a plurality of electronic apparatuses. The connection joints are disposed in the rack. The electronic apparatuses are mounted in the rack, and each of the electronic apparatuses includes a main body and a joint assembly. The main body has a plate. The joint assembly includes a mount seat, a first eccentric component, a second eccentric component, and a joint. The mount seat is disposed on the plate, and the mount seat has a first mount hole. The first eccentric component is rotatably disposed in the first mount hole. The first eccentric component has a second mount hole, and a central line of the second mount hole is non-overlapped with a central line of the first mount hole. The second eccentric component is rotatably disposed in the second mount hole. The joint is connected to the second eccentric component, a central line of the joint is non-overlapped with the central line of the second mount hole, and the joint is connected to one of the connection joints.

According to the joint assemblies, the electronic apparatuses and the rack module, the first eccentric component is rotatably disposed on the first mount hole of the mount seat, the second eccentric component is rotatably disposed on the second mount hole of the first eccentric component, the joint is connected to the second eccentric component, and the central line of the joint and the central line of the first mount hole are non-overlapped with the central line of the second mount hole. Therefore, when the central line of the joint is not aligned with the central line of the connection joint during the connection between the joint and the connection joint, the spiral rotation of the second eccentric component relative to the first eccentric component and the spiral rotation of the first eccentric component relative to the mount seat enable the central lines of the joint and the connection joint to be aligned with each other. As a result, the connection joint can be straightly and entirely inserted into the joint while there is no lateral force applied on the place where the joint is assembled with the connection joint, thereby ensuring the smooth connection between the joint and the connection joint for reducing leakage risk.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a rack module according to a first embodiment of the disclosure;

FIG. 2 is a perspective view of a connection joint and an electronic apparatus in FIG. 1;

FIG. 3 is an exploded view of the electronic apparatus in FIG. 2;

FIG. 4 is a cross-sectional view of the connection joint and the electronic apparatus in FIG. 2;

FIG. 5 is a cross-sectional view of the electronic apparatus in FIG. 4 taken along a line 5-5;

FIG. 6 is a schematic view showing movement traces of a central line of a first mount hole of a first eccentric component and a central line of a joint in FIG. 5;

FIG. 7 is a cross-sectional view of the connection joint and the electronic apparatus in FIG. 4 when the connection joint contacts the joint;

FIG. 8 is a cross-sectional view of the electronic apparatus in FIG. 7 taken along a line 8-8;

FIG. 9 is a cross-sectional view of the connection joint and the electronic apparatus in FIG. 7 when the connection joint assembled with the joint pushes the mount seat;

FIG. 10 is a perspective view of a connection joint and an electronic apparatus according to a second embodiment of the disclosure;

FIG. 11 is an exploded view of the electronic apparatus in FIG. 10;

FIG. 12 is a cross-sectional view of the connection joint and the electronic apparatus in FIG. 10;

FIG. 13 is a cross-sectional view of the electronic apparatus in FIG. 12 taken along a line 13-13; and

FIG. 14 is a perspective view of an electronic apparatus according to a third embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

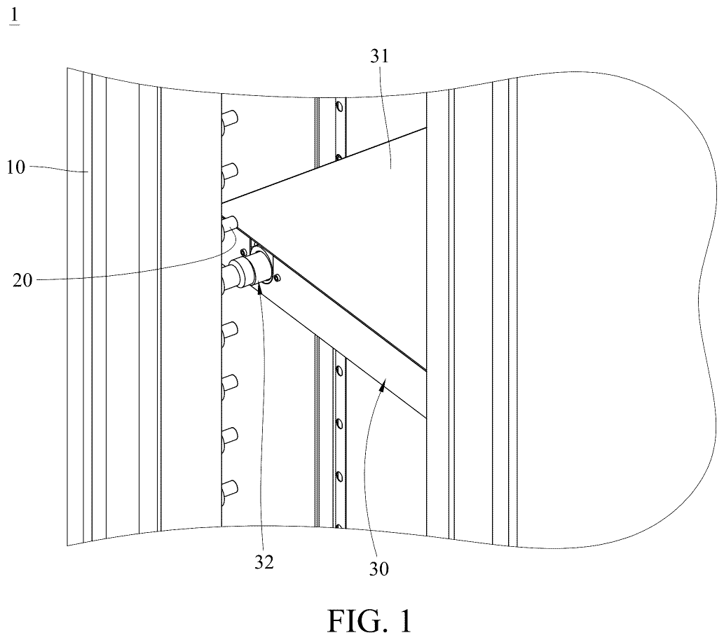

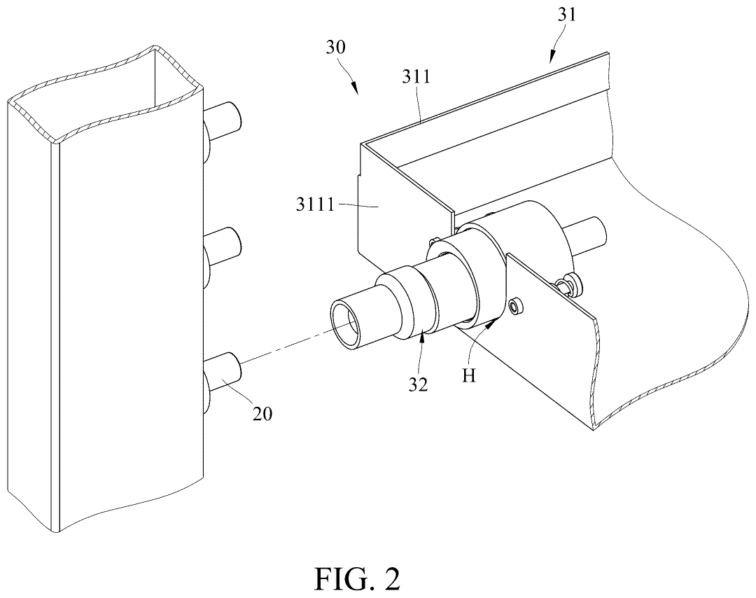

Referring to FIGS. 1 and 2, FIG. 1 is a perspective view of a rack module according to a first embodiment of the disclosure, and FIG. 2 is a perspective view of a connection joint and an electronic apparatus in FIG. 1.

In this embodiment, the rack module 1 includes a rack 10, a connection joint 20 and an electronic apparatus 30. The connection joint 20 is, for example, a joint of a manifold, and this joint may be a male joint. The connection joint 20 is disposed in the rack 10. The electronic apparatus 30 is, for example, a server. The electronic apparatus 30 is mounted in the rack 10 and includes a main body 31 and a joint assembly 32. The main body 31 includes a casing 311 and various electronic components (not shown) located in the casing 311. The casing 311 of the main body 31 has a plate 3111, and the plate 3111 is, for example, a back plate of the casing 311. The joint assembly 32 is disposed on the plate 3111 of the casing 311 of the main body 31 and is assembled with the connection joint 20. In this embodiment, the joint assembly 32 and the connection joint 20 are illustrated as a pipe joint assembly and a pipe joint, but the disclosure is not limited thereto. In the disclosure, the joint assembly and the connection joint may be other types of joints for other types of apparatuses. For example, the joint assembly and the connection joint may be an electrical joint assembly and an electrical joint assembled with each other in other types of electronic apparatuses.

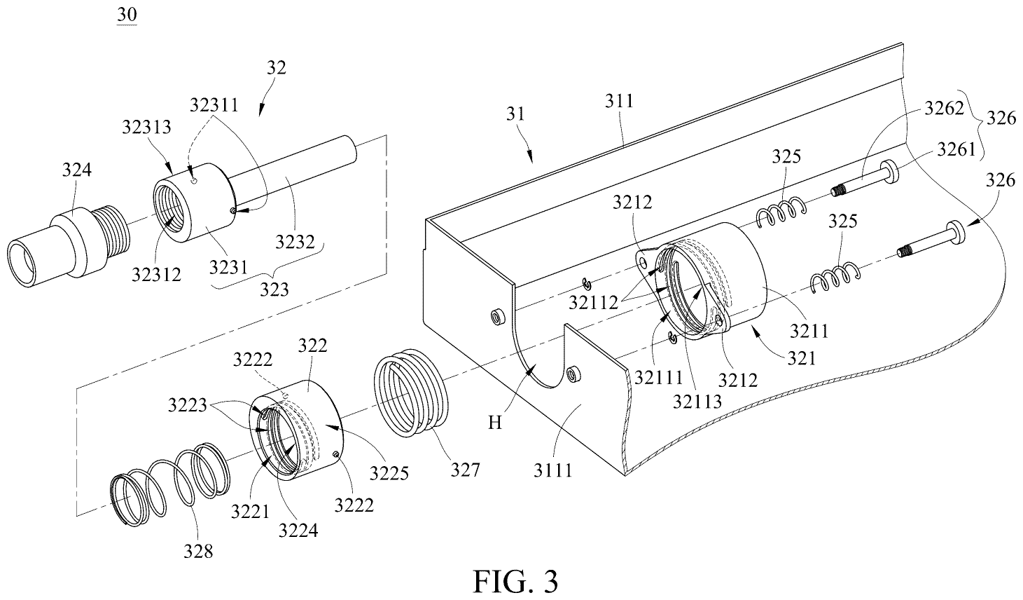

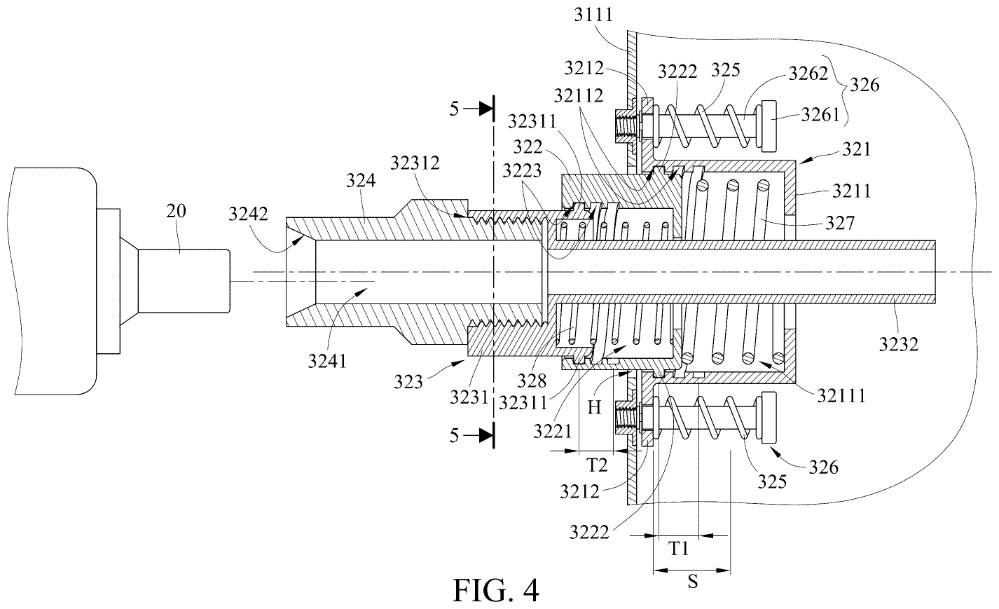

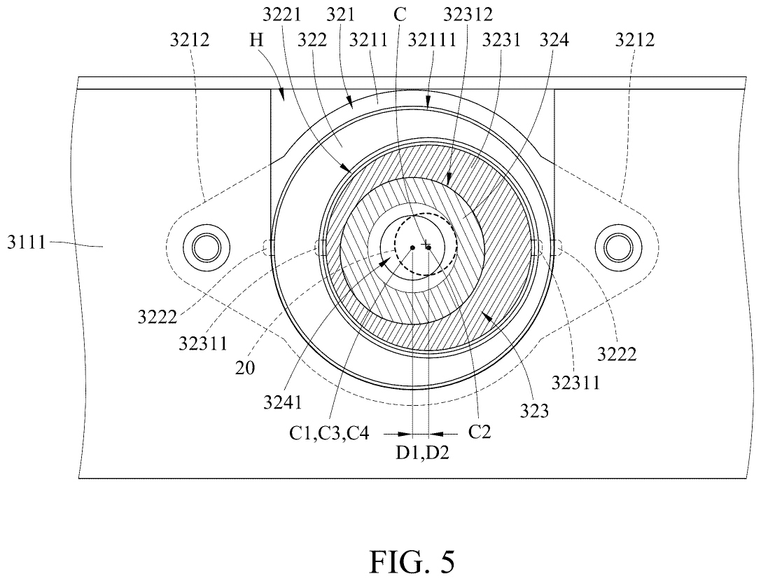

Then, the following paragraphs will specifically introduce the joint assembly 32. Referring to FIGS. 3 to 5, FIG. 3 is an exploded view of the electronic apparatus in FIG. 2, FIG. 4 is a cross-sectional view of the connection joint and the electronic apparatus in FIG. 2, and FIG. 5 is a cross-sectional view of the electronic apparatus in FIG. 4 taken along a line 5-5.

The joint assembly 32 includes a mount seat 321, a first eccentric component 322, a second eccentric component 323 and a joint 324. In addition, the joint assembly 32 may further include two first elastic components 325, two fasteners 326 and two second elastic components 327 and 328.

The plate 3111 of the casing 311 has a through hole H. The mount seat 321 is located in the casing 311, and the mount seat 321 includes a barrel portion 3211 and two protrusion portions 3212. The barrel portion 3211 has a first mount hole 32111, a first inner surface 32113 and two first guide structures 32112. The first inner surface 32113 surrounds the first mount hole 32111, and the first inner surface 32113 forms the first mount hole 32111. The first mount hole 32111 corresponds to the through hole H of the plate 3111 of the casing 311. The two first guide structures 32112 are disposed on the first inner surface 32113. Each of the first guide structures 32112 is, for example, a spiral groove, and the two first guide structures 32112 are spaced apart from each other. In this embodiment, the number of turns of each of the first guide structures 32112 is, for example, one, and the two first guide structures 32112 are offset from each other, for example, by 180 degrees. As shown in FIG. 3, one of the first guide structures 32112 spirally extends from the left side of the barrel portion 3211 and returns to the left side of the barrel portion 3211, and the other of the first guide structure 32112 spirally extends from the right side of the barrel portion 3211 and returns to the right side of the barrel portion 3211. In other words, two opposite ends of one of the first guide structures 32112 are respectively located opposite to two opposite ends of the other of the first guide structures 32112. The two protrusion portions 3212 radially protrude from two opposite sides of the barrel portion 3211, respectively.

The two fasteners 326 are, for example, bolts. Each of the fasteners 326 may include a head portion 3261 and a body portion 3262 connected to each other, where a width of the head portion 3261 is greater than a width of the body portion 3262. The two first elastic components 325 are, for example, compression springs. The two first elastic components 325 are respectively located at sides of the protrusion portions 3212 located away from the plate 3111. The body portions 3262 of the fasteners 326 are respectively disposed through the first elastic components 325 and the protrusion portions 3212 and are screwed into the plate 3111, such that the mount seat 321 is movably disposed on the plate 3111.

The first eccentric component 322 has a second mount hole 3221, a second inner surface 3224, a first outer surface 3225, two second guide structures 3222 and two third guide structures 3223. The second inner surface 3224 surrounds the second mount hole 3221, the second inner surface 3224 forms the second mount hole 3221, and the first outer surface 3225 faces away from the second inner surface 3224. The second guide structures 3222 are disposed on the first outer surface 3225. Each of the second guide structures 3222 is, for example, a protrusion, and the second guide structures are located opposite to each other. The second guide structures 3222 are movably connected to the first guide structures 32112 of the barrel portion 3211, respectively, such that the first eccentric component 322 is spirally and rotatably disposed in the first mount hole 32111 of the mount seat 321, and the first eccentric component 322 is disposed through the through hole H of the plate 3111.

Note that the quantity of the first guide structures 32112 is not restricted in the disclosure and may be modified to be one in some other embodiments. In another embodiment, the quantity of the second guide structure may be modified to be one.

The third guide structures 3223 of the first eccentric component 322 are disposed on the second inner surface 3224. Each of the third guide structures 3223 is, for example, a spiral groove. The third guide structures 3223 are spaced apart from each other. In this embodiment, the number of turns of each of the third guide structures 3223 is, for example, one, and the third guide structures 3223 are offset from each other, for example, by 180 degrees. As shown in FIG. 3, one of the third guide structured 3223 spirally extends from the left side of the first eccentric component 322 and returns to the left side of the first eccentric component 322, the other of the third guide structures 3223 spirally extends from the right side of the first eccentric component 322 and returns to the right side of the first eccentric component 322. In other words, two opposite ends of one of the third guide structures 3223 are respectively located opposite to two opposite ends of the other of the third guide structures 3223.

The second eccentric component 323 includes an eccentric portion 3231 and a coupling portion 3232 axially connected to each other. The eccentric portion 3231 has a second outer surface 32313, a third mount hole 32312 and two fourth guide structure 32311. The second outer surface 32313 faces away from the third mount hole 32312. Each of the fourth guide structures 32311 is, for example, a protrusion. The fourth guide structures 32311 are disposed on the second outer surface 32313 and located opposite to each other. The fourth guide structures3 2311 are movably connected to the third guide structures 3223 of the first eccentric component 322, respectively, such that the eccentric portion 3231 of the second eccentric component 323 is spirally and rotatably disposed in the second mount hole 3221 of the first eccentric component 322. The coupling portion 3232 extends to the first mount hole 32111 of the mount seat 321 through the second mount hole 3221 of the first eccentric component 322. The coupling portion 3232 is configured to be assembled with a pipe (not shown), such that the pipe can communicate with the third mount hole 32312 of the eccentric portion 3231 through the coupling portion 3232.

Note that the quantity of the third guide structures 3223 are not restricted in the disclosure and may be modified to be one in some other embodiments. In another embodiment, the quantity of the fourth guide structure may be modified to be one.

The joint 324 is fixed in the third mount hole 32312 of the eccentric portion 3231 of the second eccentric component 323 via threaded structure. The joint 324 is, for example, a female joint. The joint 324 has an insertion hole 3241 and an inclined guide surface 3242 located at one side of the insertion hole 3241 located farther away from the second eccentric component 323. A central line C4 of the joint 324 is, for example, overlapped with a central line C3 of the third mount hole 32312 of the second eccentric component 323.

Note that the joint 324 is not restricted to being fixed in the third mount hole 32312 of the eccentric portion 3231 of the second eccentric component 323 via threaded structure. In some other embodiments, the joint may be integrally connected to the eccentric portion of the second eccentric component.

The second elastic components 327 and 328 are, for example, compression springs. The second elastic component 327 is located in the first mount hole 32111 of the mount seat 321 and surrounds the coupling portion 3232 of the second eccentric component 323. Two opposite ends of the second elastic component 327 are respectively in contact with the first eccentric component 322 and the mount seat 321. The second elastic component 327 is configured to provide a force to the first eccentric component 322 for moving the first eccentric component 322 outwards the mount seat 321. The second elastic component 328 is located in the second mount hole 3221 of the first eccentric component 322 and surrounds the coupling portion 3232 of the second eccentric component 323. Two opposite ends of the second elastic component 328 are respectively in contact with the first eccentric component 322 and the eccentric portion 3231 of the second eccentric component 323. The second elastic component 328 is configured to provide a force to the eccentric portion 3231 of the second eccentric component 323 for moving the eccentric portion 3231 outwards the first eccentric component 322.

In this embodiment, an elastic modulus of the second elastic component 327 is, for example, equal to an elastic modulus of the second elastic component 328. In addition, an equivalent elastic modulus of the two first elastic components 325 is, for example, greater than or equal to an equivalent elastic modulus of the second elastic components 327 and 328. In other words, a force for deforming the two first elastic components 325 may be greater than a force for deforming the second elastic components 327 and 328. Moreover, maximum deformation amounts S of the first elastic components 325 may be greater than or equal to a sum of a distance T1 between two opposite ends of the first guide structure 32112 in an axial direction of the mount seat 321 and a distance T2 between two opposite ends of the third guide structure 3223 in an axial direction of the first eccentric component 322.

As shown in FIG. 4, the first eccentric component 322 and the second eccentric component 323 are located at initial positions. In other words, the second guide structures 3222 of the first eccentric component 322 are located at ends of the first guide structures 32112 of the mount seat 321 located closest to an opening of the first mount hole 32111, and the fourth guide structures 32311 of the second eccentric component 323 are located at ends of the third guide structures 3223 of the first eccentric component 322 located closest to an opening of the second mount hole 3221. At this moment, as shown in FIG. 5, a central line C1 of the first mount hole 32111 of the mount seat 321 is, for example, overlapped with the central line C4 of the joint 324.

As shown in FIG. 5, the first mount hole 32111 of the mount seat 321 and the second mount hole 3221 of the first eccentric component 322 are eccentrically arranged, and the joint 324 and the second mount hole 3221 of the first eccentric component 322 are eccentrically arranged. In other words, the central line C1 of the first mount hole 32111 of the mount seat 321 is non-overlapped with a central line C2 of the second mount hole 3221 of the first eccentric component 322, and the central line C4 of the joint 324 is non-overlapped with the central line C2 of the second mount hole 3221 of the first eccentric component 322. An offset distance D1 between the central line C4 of the joint 324 and the central line C2 of the second mount hole 3221 is, for example, equal to an offset distance D2 between the central line C2 of the second mount hole 3221 and the central line C1 of the first mount hole 32111.

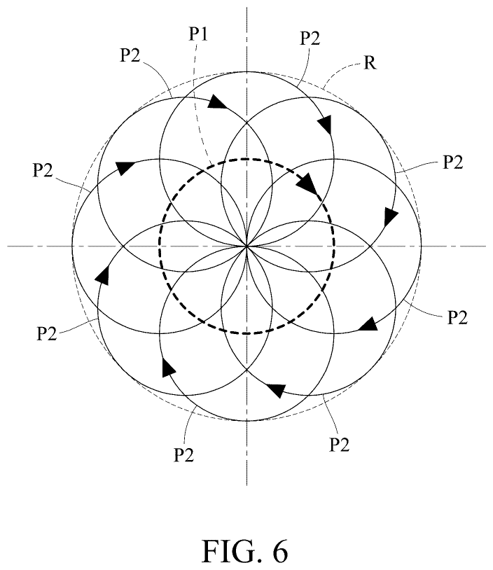

Then, referring to FIGS. 5 and 6, FIG. 6 is a schematic view showing movement traces of a central line of a first mount hole of a first eccentric component and a central line of a joint in FIG. 5. Since the second mount hole 3221 of the first eccentric component 322 and the first mount hole 32111 of the mount seat 321 are eccentrically arranged, a movement trace of the central line C2 of the second mount hole 3221 of the first eccentric component 322 during the rotation of the first eccentric component 322 relative to the mount seat 321 is presented as a circle P1. In addition, the joint 324 and the second mount hole 3221 of the first eccentric component 322 are eccentrically arranged. Therefore, when the central line C2 of the second mount hole 3221 of the first eccentric component 322 is located at different points on the circle P1, a movement trace of the central line C4 of the joint 324 is presented as infinite number of circles P2 (FIG. 6 exemplarily shows 8 circles P2) during the rotation of the joint 324 relative to the first eccentric component 322, and these circles P2 together form an area R.

As shown in FIGS. 1 and 4 to 6, in a case that the electronic apparatus 30 is moved into the rack, the joint 324 is not yet in contact with the connection joint 20, and the central line C4 of the joint 324 is not aligned with a central line C of the connection joint 20, as long as the central line C of the connection joint 20 is located in the area R, the central line C4 of the joint 324 can be moved to align with the central line C of the connection joint 20 during the connection between the joint 324 and the connection joint 20.

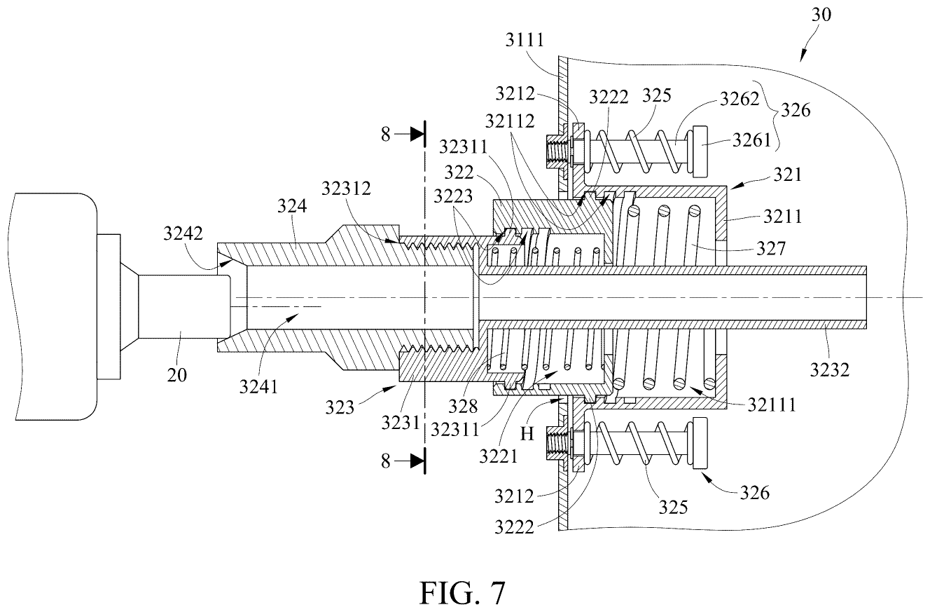

Specifically, referring to FIG. 7, FIG. 7 is a cross-sectional view of the connection joint and the electronic apparatus in FIG. 4 when the connection joint contacts the joint. When the electronic apparatus 30 (as shown in FIG. 1) is further moved into the rack 10, the connection joint 20 presses against the inclined guide surface 3242 of the joint 324 so as to force the joint 324 to spirally rotate relative to the first eccentric component 322 via the eccentric portion 3231 of the second eccentric component 323 and compress the second elastic component 328, and to force the first eccentric component 322 to spirally rotate relative to the mount seat 321 and compress the second elastic component 327.

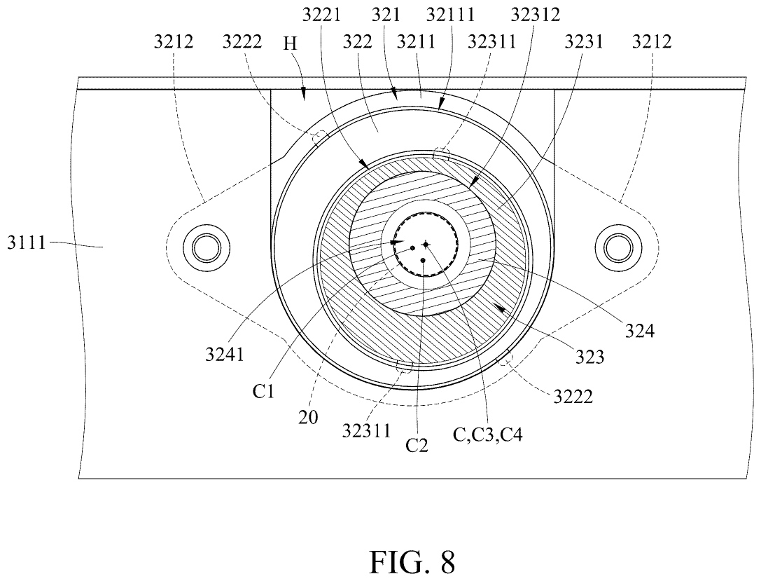

Then, referring to FIG. 8, FIG. 8 is a cross-sectional view of the electronic apparatus in FIG. 7 taken along a line 8-8. The first mount hole 32111 of the mount seat 321 and the second mount hole 3221 of the first eccentric component 322 are eccentrically arranged, and the joint 324 (or the third mount hole 32312 of the second eccentric component 323) and the second mount hole 3221 of the first eccentric component 322 are eccentrically arranged. Therefore, during the spiral rotation of the joint 324 relative to the first eccentric component 322 via the eccentric portion 3231 of the second eccentric component 323 and the spiral rotation of the first eccentric component 322 relative to the mount seat 321, the central line C4 of the joint 324 is moved so as to be aligned with the central line C of the connection joint 20. As a result, the connection joint 20 can be straightly and entirely inserted into the insertion hole 3241 of the joint 324 while there is no lateral force applied on the place where the joint 324 is assembled with the connection joint 20, thereby ensuring the smooth connection between the joint 324 and the connection joint 20 for reducing leakage risk.

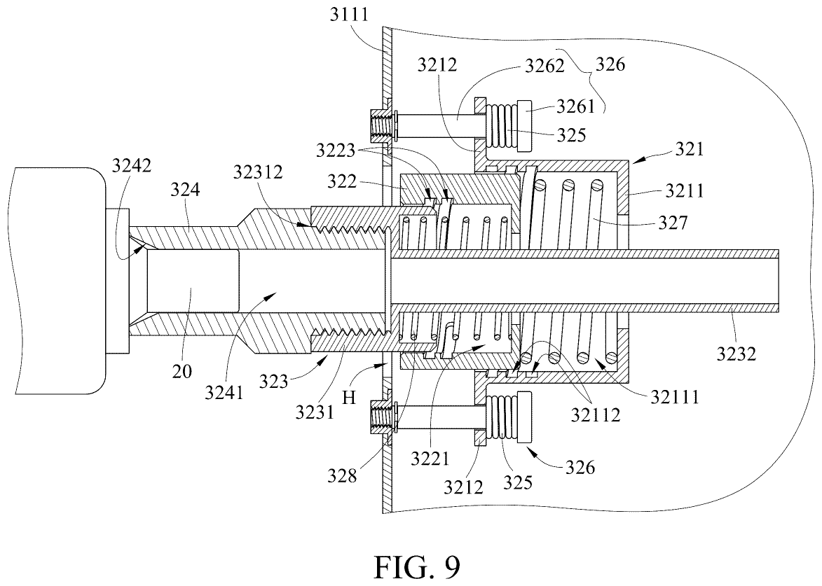

Then, referring to FIG. 9, FIG. 9 is a cross-sectional view of the connection joint and the electronic apparatus in FIG. 7 when the connection joint assembled with the joint pushes the mount seat. When the connection joint 20 is entirely inserted into the insertion hole 3241 of the joint 324, the joint 324 is no longer rotated relative to the first eccentric component 322, and the first eccentric component 322 is no longer rotated relative to the mount seat 321. At this moment, when the electronic apparatus 30 (as shown in FIG. 1) is further moved into the rack, the mount seat 321 is forced to move away from the plate 3111, such that the protrusion portions 3212 of the mount seat 321 are moved towards the head portions 3261 of the fasteners 326 so as to compress the first elastic components 325. As a result, the connection between the joint 324 and the connection joint 20 is finished.

In this embodiment, the offset distance D1 between the central line C4 of the joint 324 and the central line C2 of the second mount hole 3221 is equal to the offset distance D2 between the central line C2 of the second mount hole 3221 and the central line C1 of the first mount hole 32111, which enables the area R formed by the movement trace of the central line C4 of the joint 324 to substantially be a solid circular area, and thus the central line C4 of the joint 324 can be aligned with the central line C of the connection joint 20 in more different positions.

Note that the offset distance D1 between the central line C4 of the joint 324 and the central line C2 of the second mount hole 3221 is not restricted to being equal to the offset distance D2 between the central line C2 of the second mount hole 3221 and the central line C1 of the first mount hole 32111. In some other embodiments, the offset distance between the central line of the joint and the central line of the second mount hole may be greater than the offset distance between the central line of the second mount hole and the central line of the first mount hole.

In this embodiment, the cooperation of the first guide structures 32112 of the mount seat 321 and the second guide structures 3222 of the first eccentric component 322 can guide the first eccentric component 322 to spirally rotate relative to the mount seat 321, and the cooperation of the third guide structures 3223 of the first eccentric component 322 and the fourth guide structures 32311 of the second eccentric component 323 can guide the second eccentric component 323 to spirally rotate relative to the first eccentric component 322.

Note that the quantities and types of the first guide structures 32112, the second guide structures 3222, the third guide structures 3223 and the fourth guide structures 32311 are not restricted in the disclosure. In some other embodiments, the quantities of them may be one, the first guide structure and the third guide structure may be protrusions, and the second guide structure and the fourth guide structure may be spiral grooves.

In this embodiment, the elastic modulus of the second elastic component 327 is equal to the elastic modulus of the second elastic component 328, and the equivalent elastic modulus of the two first elastic components 325 is greater than or equal to an equivalent elastic modulus of the second elastic components 327 and 328, which ensures the first eccentric component 322 and the second eccentric component 323 are spirally rotated together, and the spiral rotations of the first eccentric component 322 and the second eccentric component 323 may happen earlier than the horizontal movement of the mount seat 321 relative to the plate 3111. As a result, the connection joint 20 and the joint 324 can be ensured to be completely connected first, then the horizontal movement of the mount seat 321 relative to the plate 3111 absorbs the remaining stroke of the electronic apparatus 30 into the rack.

In addition, the maximum deformation amounts S of the first elastic components 325 may be greater than or equal to a sum of a distance T1 between two opposite ends of the first guide structure 32112 in an axial direction of the mount seat 321 and a distance T2 between two opposite ends of the third guide structures 3223 in an axial direction of the first eccentric component 322, which ensures even if the connection joint 20 and the joint 324 has already been completely connected to each other after the first eccentric component 322 and the second eccentric component 323 are spirally rotated very small stroke, the horizontal movement distance of the mount seat 321 relative to the plate 3111 allowed by the maximum deformation amounts S of the first elastic components 325 can absorb the remaining stroke of the electronic apparatus 30 into the rack.

After the joint 3214 is removed from the connection joint 20, the first elastic components 325 move the mount seat 321 back to its original position, and the second elastic components 327 and 328 respectively move the first eccentric component 322 and the second eccentric component 323 back to its original positions.

Note that the quantity of the first elastic components 325 is not restricted in the disclosure and may be modified to be one in some other embodiments, and the quantity of the fastener may be modified to be one correspondingly. In addition, the first elastic component is an optional component and may be omitted in some other embodiments, and the fastener may be omitted correspondingly. In such a case, the movement of the mount seat may be guided by other components or structures, and the mount seat may be manually moved back to its original position. On the other hand, the second elastic components 327 and 328 are optional components and may be omitted in some other embodiments. In such a case, the first eccentric component and the second eccentric component may be manually moved back to its original positions.

Furthermore, the aforementioned connection joint 20 and joint 324 are not restricted to being the male joint and the female joint, respectively. In some other embodiments, the connection joint and the joint may be the female joint and the male joint, respectively.

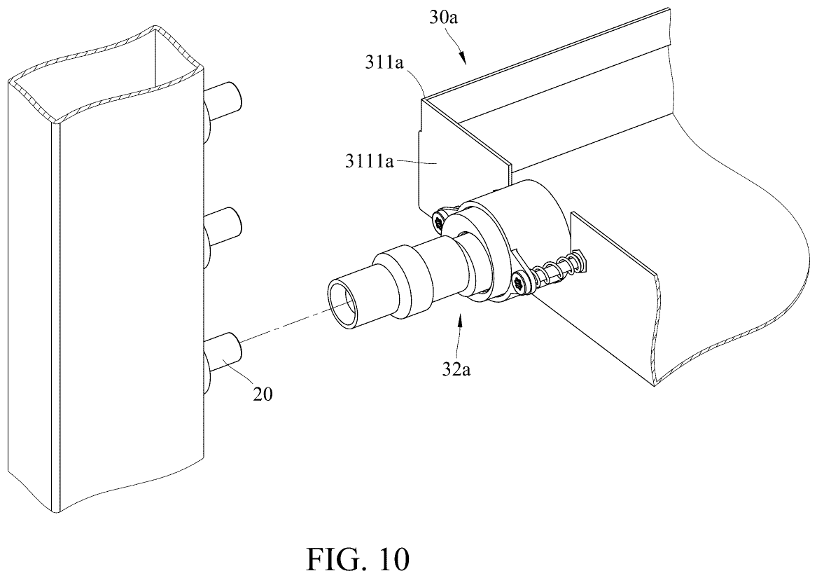

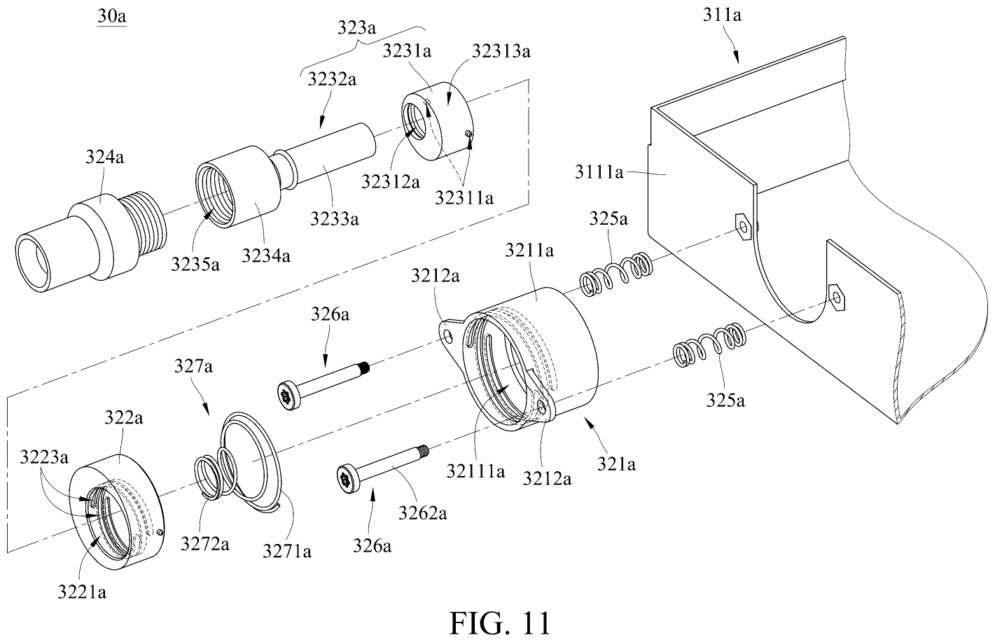

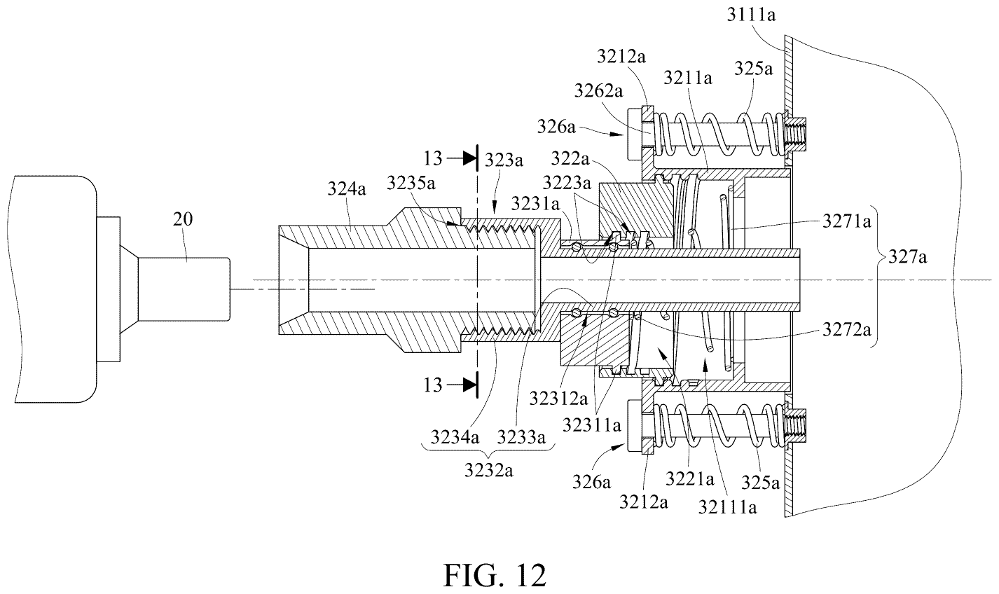

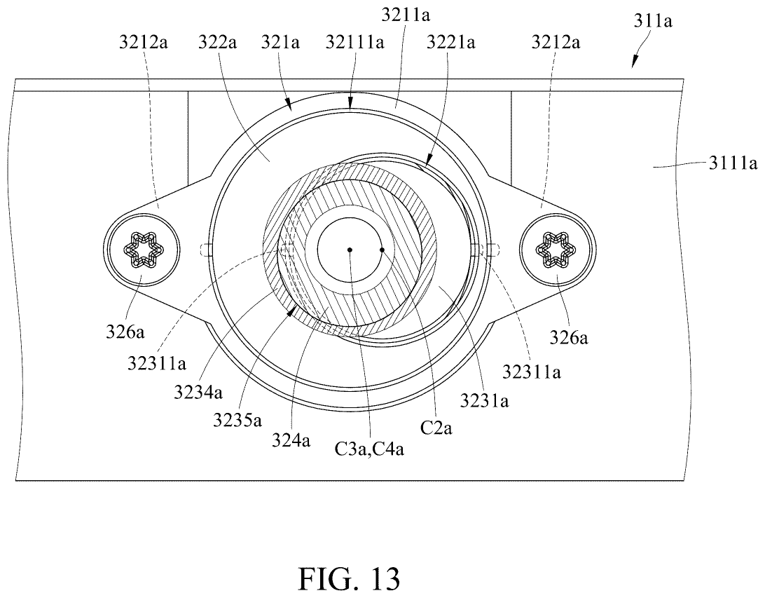

Then, referring to FIGS. 10 to 13, FIG. 10 is a perspective view of a connection joint and an electronic apparatus according to a second embodiment of the disclosure, FIG. 11 is an exploded view of the electronic apparatus in FIG. 10, FIG. 12 is a cross-sectional view of the connection joint and the electronic apparatus in FIG. 10, and FIG. 13 is a cross-sectional view of the electronic apparatus in FIG. 12 taken along a line 13-13.

The electronic apparatus 30a of this embodiment is similar to the electronic apparatus 30 with reference to FIGS. 1 to 9, and the following paragraphs will describe the differences between them while the same part will not be repeatedly introduced hereinafter.

In this embodiment, a part of a barrel portion 3211a and two protrusion portions 3212a of a mount seat 321a of a joint assembly 32a is located outside a casing 311a. Two first elastic components 325a are respectively located between the protrusion portions 3212a of the mount seat 321a and a plate 3111a of the casing 311a. Body portions 3262a of two fasteners 326a are respectively disposed through the protrusion portions 3212a and the first elastic components 325a and are screwed into the plate 3111a. Since a part of the barrel portion 3211a and the protrusion portions 3212a of the mount seat 321a are located outside the casing 311a, the fasteners 326a can mount the mount seat 321a on the plate 3111a from outside of the casing 311a, which facilitates the installation process.

In this embodiment, a second eccentric component 323a includes an eccentric portion 3231a and a coupling portion 3232a. The eccentric portion 3231a has an outer surface 32313a, a third mount hole 32312a and two fourth guide structures 32311a. The outer surface 32313a faces away from the third mount hole 32312a. The fourth guide structures 32311a of the eccentric portion 3231a are disposed on the outer surface 32313a and located opposite to each other. The fourth guide structures 32311a are movably connected to two third guide structures 3223a in a second mount hole 3221a of a first eccentric component 322a, respectively, such that the eccentric portion 3231a is spirally and rotatably disposed in the second mount hole 3221a of the first eccentric component 322a. The third mount hole 32312a and the second mount hole 3221a are eccentrically arranged; that is, a central line C3a of the third mount hole 32312a is non-overlapped with a central line C2a of the second mount hole 3221a. The coupling portion 3232a, for example, includes a pipe mount part 3233a and a joint mount part 3234a coaxially connected to each other. An outer diameter of the joint mount part 3234a is greater than an outer diameter of the pipe mount part 3233a. The pipe mount part 3233a is rotatably disposed through the third mount hole 32312a and extends to a first mount hole 32111a of the mount seat 321a through the second mount hole 3221a of the first eccentric component 322a. The joint mount part 3234a is in contact with one side of the eccentric portion 3231a, and the joint mount part 3234a has a fourth mount hole 3235a. The fourth mount hole 3235a and the third mount hole 32312a are coaxially arranged. In other words, a central line C4a of the fourth mount hole 3235a is overlapped with the central line C3a of the third mount hole 32312a. The joint 324a is fixed in the fourth mount hole 3235a.

In this embodiment, the joint assembly 32a includes only one second elastic component 327a. The second elastic component 327a includes a wide portion 3271a and a narrow portion 3272a connected to each other. A maximum outer diameter of the wide portion 3271a is greater than a maximum outer diameter of the narrow portion 3272a. The wide portion 3271a is located in the first mount hole 32111a of the mount seat 321a and is in contact with the first eccentric component 322a. The wide portion 3271a is configured to provide a force to the first eccentric component 322a for moving the first eccentric component 322a outwards the mount seat 321a. The narrow portion 3272a is located in the second mount hole 3221a of the first eccentric component 322a and is in contact with the eccentric portion 3231a. The narrow portion 3272a is configured to provide a force the eccentric portion 3231a of the second eccentric component 323a for moving the eccentric portion 3231a outwards the first eccentric component 322a.

During the connection between the connection joint 20 and the joint 324a whose central lines are non-overlapped to each other, the connection joint 20 pushes the eccentric portion 3231a of the second eccentric component 323a via the joint 324a and the joint mount part 3234a of the coupling portion 3232a of the second eccentric component 323a, and pushes the first eccentric component 322a via the eccentric portion 3231a of the second eccentric component 323a, such that the eccentric portion 3231a is spirally rotated relative to the first eccentric component 322a and compresses the narrow portion 3272a of the second elastic component 327a, and the first eccentric component 322a is spirally rotated relative to the mount seat 321a and compresses the wide portion 3271a of the second elastic component 327a.

In this embodiment, the pipe mount part 3233a of the coupling portion 3232a of the second eccentric component 323a is rotatably disposed through the third mount hole 32312a of the eccentric portion 3231a; that is, the pipe mount part 3233a of the coupling portion 3232a and the eccentric portion 3231a of the second eccentric component 323a are rotatable relative to each other. Therefore, during the aforementioned spiral rotation of the eccentric portion 3231a relative to the first eccentric component 322a, the coupling portion 3232a of the second eccentric component 323a is not rotated, which prevents the pipe mounted on the pipe mount part 3233a of the coupling portion 3232a from being twisted, thereby prevent the damage of the pipe.

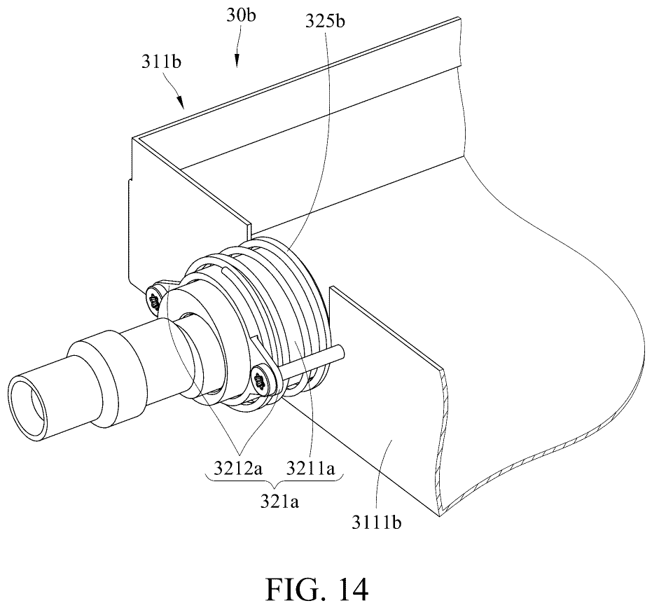

Then, referring to FIG. 14, FIG. 14 is a perspective view of an electronic apparatus according to a third embodiment of the disclosure.

The electronic apparatus 30b of this embodiment is similar to the electronic apparatus 30a with reference to FIGS. 10 to 13, and the following paragraphs will describe the differences between them while the same part will not be repeatedly introduced hereinafter.

In this embodiment, there is only one first elastic component 325b. The first elastic component 325b is sleeved on a barrel portion 3211b of a mount seat 321b, and the first elastic component 325b is located between two protrusion portions 3212b of the mount seat 321b and a plate 3111b of a casing 311b.

According to the joint assemblies, the electronic apparatuses and the rack module, the first eccentric component is spirally and rotatably disposed on the first mount hole of the mount seat, the second eccentric component is spirally and rotatably disposed on the second mount hole of the first eccentric component, the joint is connected to the second eccentric component, and the central line of the joint and the central line of the first mount hole are non-overlapped with the central line of the second mount hole. Therefore, when the central line of the joint is not aligned with the central line of the connection joint during the connection between the joint and the connection joint, the spiral rotation of the second eccentric component relative to the first eccentric component and the spiral rotation of the first eccentric component relative to the mount seat enable the central lines of the joint and the connection joint to be aligned with each other. As a result, the connection joint can be straightly and entirely inserted into the joint while there is no lateral force applied on the place where the joint is assembled with the connection joint, thereby ensuring the smooth connection between the joint and the connection joint for reducing leakage risk.

In addition, the offset distance between the central line of the joint and the central line of the second mount hole is greater than or equal to the offset distance between the central line of the second mount hole and the central line of the first mount hole, which enables the area formed by the movement trace of the central line of the joint to be a solid circular area substantially, and thus the central line of the joint can be aligned with the central line of the connection joint in more different positions.

Moreover, the elastic moduli of the two second elastic component are equal to each other, and the equivalent elastic modulus of the two first elastic components is greater than or equal to the equivalent elastic modulus of the second elastic components, which ensures when the joint is pressed by the connection joint, the first eccentric component and the second eccentric component are spirally rotated together, and the spiral rotations of the first eccentric component and the second eccentric component may happen earlier than the horizontal movement of the mount seat relative to the plate. As a result, the connection joint and the joint can be ensured to be completely connected first, then the horizontal movement of the mount seat relative to the plate absorbs the remaining stroke of the electronic apparatus into the rack.

On the other hand, the pipe mount part of the coupling portion and the eccentric portion of the second eccentric component are rotatable relative to each other. Therefore, during the spiral rotation of the eccentric portion relative to the first eccentric component, the coupling portion of the second eccentric component is not rotated, which prevents the pipe mounted on the pipe mount part of the coupling portion from being twisted, thereby prevent the damage of the pipe.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A joint assembly, configured to be disposed on a plate, the joint assembly comprising:
a mount seat, configured to be disposed on the plate, wherein the mount seat has a first mount hole;
a first eccentric component, rotatably disposed in the first mount hole, wherein the first eccentric component has a second mount hole, and a central line of the second mount hole is non-overlapped with a central line of the first mount hole;
a second eccentric component, rotatably disposed in the second mount hole; and
a joint, connected to the second eccentric component, wherein a central line of the joint is non-overlapped with the central line of the second mount hole.

2. The joint assembly according to claim 1, wherein the mount seat has a first inner surface and at least one first guide structure, the first inner surface forms the first mount hole, the at least one first guide structure is disposed on the first inner surface, the first eccentric component has a second inner surface, an outer surface, at least one second guide structure and at least one third guide structure, the second inner surface forms the second mount hole, the at least one second guide structure is disposed on the outer surface, the at least one third guide structure is disposed on the second inner surface, the at least one second guide structure is movably connected to the at least one first guide structure, the second eccentric component has at least one fourth guide structure, and the at least one fourth guide structure is movably connected to the at least one third guide structure.

3. The joint assembly according to claim 2, wherein each of the at least one first guide structure and the at least one third guide structure is a spiral groove, and each of the at least one second guide structure and the at least one fourth guide structure is a protrusion.

4. The joint assembly according to claim 3, wherein the at least one first guide structure comprises two first guide structures, the at least one third guide structure comprises two third guide structures, the at least one second guide structure comprises two second guide structures, the at least one fourth guide structure comprises two fourth guide structures, the two second guide structures are respectively movably connected to the two first guide structures, and the two fourth guide structures are respectively movably connected to the two third guide structures.

5. The joint assembly according to claim 2, wherein the second eccentric component comprises an eccentric portion and a coupling portion axially connected to each other, the eccentric portion is rotatably disposed in the second mount hole, the eccentric portion has a third mount hole, a central line of the third mount hole is non-overlapped with the central line of the second mount hole, the joint is fixed in the third mount hole, and the coupling portion extends to the first mount hole through the second mount hole.

6. The joint assembly according to claim 2, wherein the second eccentric component comprises an eccentric portion and a coupling portion, the eccentric portion is rotatably disposed in the second mount hole, the eccentric portion has a third mount hole, a central line of the third mount hole is non-overlapped with a central line of the second mount hole, the coupling portion is rotatably disposed in the third mount hole, the coupling portion has a fourth mount hole, a central line of the fourth mount hole and the central line of the third mount hole are overlapped with each other, and the joint is fixed in the fourth mount hole.

7. The joint assembly according to claim 1, further comprising at least one first elastic component, wherein the mount seat is configured to be movably disposed on the plate, the mount seat comprises a barrel portion and at least one protrusion portion, the at least one protrusion portion radially protrudes from the barrel portion, the at least one first elastic component is located at one side of the at least one protrusion portion located away from the plate, or the at least one first elastic component is located between the at least one protrusion portion and the plate.

8. The joint assembly according to claim 7, further comprising at least one fastener, wherein the at least one fastener comprises a head portion and a body portion connected to each other, a width of the head portion is greater than a width of the body portion, the at least one first elastic component is located at one side of the at least one protrusion portion located away from the plate, and the body portion is disposed through the at least one first elastic component and the at least one protrusion portion and is configured to be mounted on the plate.

9. The joint assembly according to claim 7, further comprising at least one fastener, wherein the at least one first elastic component is located between the at least one protrusion portion and the plate, and the at least one fastener is disposed through the at least one protrusion portion and is configured to be mounted on the plate.

10. The joint assembly according to claim 9, wherein the at least one fastener comprises a head portion and a body portion connected to each other, a width of the head portion is greater than a width of the body portion, the body portion is disposed through the at least one protrusion portion and the at least one first elastic component and is configured to be mounted on the plate.

11. The joint assembly according to claim 7, further comprising a second elastic component, wherein the second elastic component comprises a wide portion and a narrow portion connected to each other, a maximum outer diameter of the wide portion is greater than a maximum outer diameter of the narrow portion, the wide portion is located in the first mount hole of the mount seat and is in contact with the first eccentric component, the narrow portion is located in the second mount hole of the first eccentric component and is in contact with the second eccentric component.

12. The joint assembly according to claim 7, further comprising two second elastic components, wherein one of the two second elastic components is located in the first mount hole of the mount seat and is in contact with the first eccentric component, and the other of the two second elastic components is located in the second mount hole of the first eccentric component and is in contact with the second eccentric component.

13. The joint assembly according to claim 12, wherein an equivalent elastic modulus of the at least one first elastic component is greater than or equal to an equivalent elastic modulus of the two second elastic components.

14. The joint assembly according to claim 1, wherein an offset distance between the central line of the joint and the central line of the second mount hole is greater than or equal to an offset distance between the central line of the second mount hole and the central line of the first mount hole.

15. An electronic apparatus, comprising:
a main body, having a plate; and
a joint assembly, comprising:
a mount seat, disposed on the plate, wherein the mount seat has a first mount hole;
a first eccentric component, rotatably disposed in the first mount hole, wherein the first eccentric component has a second mount hole, a central line of the second mount hole is non-overlapped with a central line of the first mount hole;
a second eccentric component, rotatably disposed in the second mount hole; and
a joint, connected to the second eccentric component, wherein a central line of the joint is non-overlapped with the central line of the second mount hole.

16. The electronic apparatus according to claim 15, wherein the mount seat has a first inner surface and at least one first guide structure, the first inner surface forms the first mount hole, the at least one first guide structure is disposed on the first inner surface, the first eccentric component has a second inner surface, an outer surface, at least one second guide structure and at least one third guide structure, the second inner surface forms the second mount hole, the at least one second guide structure is disposed on the outer surface, the at least one third guide structure is disposed on the second inner surface, the at least one second guide structure is movably connected to the at least one first guide structure, the second eccentric component has at least one fourth guide structure, and the at least one fourth guide structure is movably connected to the at least one third guide structure.

17. The electronic apparatus according to claim 16, wherein the at least one first guide structure comprises two first guide structures, the at least one third guide structure comprises two third guide structures, each of the two first guide structures and the two third guide structures is a spiral groove, the at least one second guide structure comprises two second guide structures, the at least one fourth guide structure comprises two fourth guide structures, each of the two second guide structures and the two fourth guide structures is a protrusion, the two second guide structures are respectively movably connected to the two first guide structures, and the two fourth guide structures are respectively movably connected to the two third guide structures.

18. A rack module, comprising:
a rack;
a plurality of connection joints, disposed in the rack; and
a plurality of electronic apparatuses, mounted in the rack, wherein each of the plurality of electronic apparatuses comprises:
a main body, having a plate; and
a joint assembly, comprising:
a mount seat, disposed on the plate, wherein the mount seat has a first mount hole;
a first eccentric component, rotatably disposed in the first mount hole, wherein the first eccentric component has a second mount hole, and a central line of the second mount hole is non-overlapped with a central line of the first mount hole;
a second eccentric component, rotatably disposed in the second mount hole; and
a joint, connected to the second eccentric component, wherein a central line of the joint is non-overlapped with the central line of the second mount hole, and the joint is connected to one of the plurality of connection joints.

19. The rack module according to claim 18, wherein the mount seat has a first inner surface and at least one first guide structure, the first inner surface forms the first mount hole, the at least one first guide structure is disposed on the first inner surface, the first eccentric component has a second inner surface, an outer surface, at least one second guide structure and at least one third guide structure, the second inner surface forms the second mount hole, the at least one second guide structure is disposed on the outer surface, the at least one third guide structure is disposed on the second inner surface, the at least one second guide structure is movably connected to the at least one first guide structure, the second eccentric component has at least one fourth guide structure, and the at least one fourth guide structure is movably connected to the at least one third guide structure.

20. The rack module according to claim 19, wherein the at least one first guide structure comprises two first guide structures, the at least one third guide structure comprises two third guide structures, each of the two first guide structures and the two third guide structures is a spiral groove, the at least one second guide structure comprises two second guide structures, the at least one fourth guide structure comprises two fourth guide structures, each of the two second guide structures and the two fourth guide structures is a protrusion, the two second guide structures are respectively movably connected to the two first guide structures, and the two fourth guide structures are respectively movably connected to the two third guide structures.
